(19) United States
(12) Patent Application Publication
(10) Pub. No.: US 2026/0293628 A1
(43) Pub. Date: Sep. 24, 2026

(54) BONDED DIE STRUCTURES WITH BACKSIDE POWER DISTRIBUTION NETWORK AND INTEGRATED FUNCTONAL DIES AND METHODS OF FORMING THE SAME

(71) Applicant: Taiwan Semiconductor Manufacturing Company Limited, Hsinchu (TW)

(72) Inventors: Hsien-Wei CHEN, Hsinchu City (TW); Monsen LIU, Hsinchu (TW); Chieh-Lung LAI, Taichung City (TW); Meng-Liang LIN, Hsinchu (TW)

(21) Appl. No.: 19/082,447

(22) Filed: Mar. 18, 2025

(51) Int. Cl. H01L 23/00; H01L 21/768; H01L 23/528; H01L 25/16

(52) U.S. Cl. CPC H10W 20/023; H10W 20/43; H10W 90/00; H10W 80/312; H10W 80/327; H10W 90/792

(57) ABSTRACT

Bonded die structures including a first semiconductor die having a back-side power distribution network (PDN) and at least one additional functional die bonded to the first semiconductor die at a bonding interface. The additional functional die may include a memory die bonded over a front side of the first semiconductor die opposite the PDN. Alternatively, or in addition, the at least one functional die may include a deep trench capacitor (DTC) die bonded over the PDN on the back side of the first semiconductor die. Various embodiments may provide increased functionality of a bonded die structure with improved signal integrity and power integrity.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view illustrating a portion of a first device structure according to various embodiments of the present disclosure.

FIG. 1B is a vertical cross-sectional view illustrating a portion of a second device structure according to various embodiments of the present disclosure.

FIG. 2 is a vertical cross-sectional view illustrating the second device structure bonded to the first device structure to form a bonded device structure according to various embodiments of the present disclosure.

FIG. 3 is a vertical cross-sectional view illustrating the bonded device structure in an inverted orientation such that the first device structure is located over the second device structure according to various embodiments of the present disclosure.

FIG. 4 is a vertical cross-sectional view of the bonded device structure following a thinning process to remove a backside portion of the first semiconductor substrate according to various embodiments of the present disclosure.

FIG. 5 is a vertical cross-sectional view of the bonded device structure illustrating vias formed in the first semiconductor substrate and a power distribution network (PDN) structure formed over the backside of the first semiconductor substrate according to various embodiments of the present disclosure.

FIG. 6A is a vertical cross-sectional view illustrating a portion of a third device structure according to various embodiments of the present disclosure.

FIG. 6B is an enlarged vertical cross-sectional view of a portion of the third device structure that illustrates a deep trench capacitor (DTC) structure according to various embodiments of the present disclosure.

FIG. 7 is a vertical cross-sectional view of the bonded device structure including the third device structure bonded over the PDN structure according to various embodiments of the present disclosure.

FIG. 8 is a vertical cross-sectional view of the bonded device structure following a thinning process to remove a backside portion of the third semiconductor substrate according to various embodiments of the present disclosure.

FIG. 9 is a vertical cross-sectional view of the bonded device structure including bonding structures located over the backside of the third semiconductor substrate according to various embodiments of the present disclosure.

FIG. 10 is a vertical cross-sectional view of a bonded die structure according to various embodiments of the present disclosure.

FIG. 11 is a flowchart illustrating a method of fabricating a bonded die structure according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to bonded die structures that include a first semiconductor die which include a first semiconductor substrate having a front side and a back side, first devices located on or in the front side of the semiconductor substrate, an interconnect structure over the front side of the semiconductor substrate, and a power distribution network located on the back side of the semiconductor substrate. At least one additional functional die may be bonded to the first semiconductor die at a bonding interface. In some embodiments, an additional functional die may include a memory die bonded over the front side of the first semiconductor substrate such that the interconnect structure is located between the memory die and the first semiconductor substrate. Alternatively, or in addition, an additional functional die may include a deep trench capacitor (DTC) die bonded over the back side of the first semiconductor substrate such that the power distribution network is located between the DTC die and the first semiconductor substrate.

Semiconductor integrated circuits may include a semiconductor material substrate, such as a silicon substrate, having a number of circuit components and elements formed on and/or within the semiconductor material. Semiconductor integrated circuits are typically fabricated by sequentially depositing insulating or dielectric layers, conductive layers, and semiconductive layers of material over the semiconductor substrate (e.g., a wafer), and patterning the various material layers using lithography to form integrated circuits. Portions of the semiconductor substrate containing separate integrated circuits thereon may then be separated (i.e., singulated) from the remainder of the semiconductor substrate via a dicing process to provide individual semiconductor dies.

In many semiconductor dies, integrated circuit devices, such as transistors, are formed on or in a first side (e.g., the front side) of a semiconductor substrate. An interconnect structure including metal features embedded in a dielectric material may also be formed over the front side of the semiconductor substrate to provide electrical connections to and between the various integrated circuit devices of the semiconductor die. This typically means that the power signals for the die (e.g., positive power supply voltage, ground, negative supply voltage, etc.) are transmitted within the interconnect structure together with the internal or “I/O” signals of the die, such as control signals, data signals, address signals, clock signals, etc. This may result in excessive noise which may negatively affect the performance of the die.

In an alternative configuration, a power distribution network (PDN) may be formed over the second side (i.e., the back side) of the semiconductor substrate of the semiconductor die and may be electrically connected to the integrated circuit devices via through-substrate vias (TSVs) formed within the semiconductor substrate. The PDN located on the back side of the semiconductor substrate may be referred to as a “back-side power distribution network,” or “B/S PDN.” The B/S PDN may be similar to the interconnect structure over the front side of the semiconductor substrate but may be used to provide the power signals for the die. Accordingly, power signals and I/O signals of the die may be located on opposite sides of the semiconductor substrate of the die, which may mitigate noise and improve die performance.

To fabricate a semiconductor die with a back-side power distribution network, an interconnect structure as described above may be formed over the front side of the semiconductor substrate. The interconnect structure may be bonded or otherwise adhered to a carrier substrate, such as a semiconductor substrate. The device may then be flipped over and the back-side power distribution network may be formed over the back side of the semiconductor substrate. Bonding structures, such as microbump bonding structures, solder bumps, etc., may be formed over the back-side power distribution network to enable the semiconductor die to be mounted to a separate support structure.

Various embodiments of the present disclosure include bonded die structures including a first semiconductor die having a back-side power distribution network and at least one additional functional die bonded to the first semiconductor die at a bonding interface. The first semiconductor die may be a logic die, such as a system-on-chip (SOC) die, including integrated circuit devices and a first interconnect structure on a front side of a first semiconductor substrate, and a back-side power distribution network on the back side of the first semiconductor substrate.

In some embodiments, the at least one additional functional die may be a memory die (e.g., a RAM die) including memory devices and a second interconnect structure on a second semiconductor substrate. The memory die may be mechanically and electrically coupled to the first semiconductor die at a first bonding interface between the first interconnect structure of the first semiconductor die and the second interconnect structure of the memory die. In some embodiments, the first bonding interface may be formed via a direct bonding process, such as a metal-to-metal (M-M) and dielectric-to-dielectric (D-D) bonding process.

In various embodiments, the memory die may function as a substitute for the carrier substrate as described above. That is, the first semiconductor substrate having integrated circuit devices and a first interconnect structure formed thereon may be bonded to a second semiconductor substrate including memory devices and a second interconnect structure prior to forming the back-side power distribution network. This may increase the functionality of the bonded die structure by providing a memory die bonded to the logic die rather than a non-functional carrier substrate as in related devices. Further, by providing a power distribution network on the back side of the first semiconductor die (i.e., on the side of the first semiconductor die opposite the memory die), noise may be reduced and the signal integrity of signaling between the first semiconductor die and the memory die may be enhanced.

Alternatively, or in addition, the at least one functional die may include a deep trench capacitor (DTC) die. The DTC die may include a semiconductor substrate having through-substrate vias (TSVs) and a plurality of deep trench capacitor structures formed therein. The DTC die may be mechanically and electrically coupled to the first semiconductor die at a second bonding interface between the DTC die and the back-side power distribution network of the first semiconductor die. In some embodiments, the second bonding interface may be formed via a direct bonding process, such as a metal-to-metal (M-M) and dielectric-to-dielectric (D-D) bonding process. Bonding structures, such as microbump bonding structures, solder bumps, etc., may be formed over the DTC die. In various embodiments, the DTC die may help to improve signal integrity, reduce noise and minimize parasitic effects in the bonded die structure.

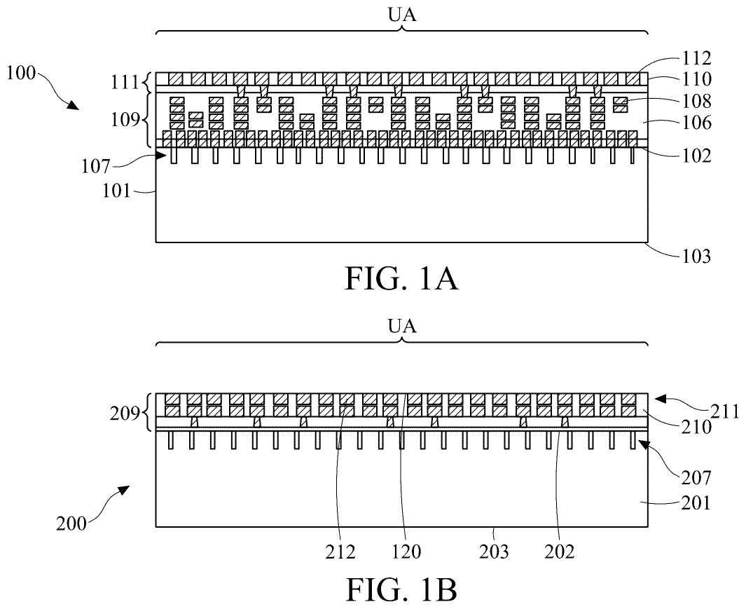

FIGS. 1A-10 are sequential vertical cross-sectional views illustrating the intermediate structures during a process of fabricating a bonded die structure according to various embodiments of the present disclosure. FIG. 1A is a vertical cross-sectional view illustrating a portion of a first device structure 100 according to various embodiments of the present disclosure. The first device structure 100 may include a first semiconductor substrate 101 (e.g., a semiconductor wafer) that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 101 may be a semiconductor-on-insulator (SOI) substrate. The first semiconductor substrate 101 may include a first side 102 (i.e., front side) and a second side 103 (i.e., backside).

The first device structure 100 may include a plurality of first devices 107 disposed on and/or in the front side 102 of the first semiconductor substrate 101. The first devices 107 may include, for example, active devices, passive devices, or a combination thereof. In some embodiments, the first devices 107 may include integrated circuit devices. The integrated circuit devices may include, for example, transistors (e.g., field-effect transistors (FETs), capacitors, resistors, diodes, photodiodes, fuse devices, or other similar devices. In some embodiments, the integrated circuit devices may include gate electrodes, source/drain regions, spacers, isolation trenches, and the like.

The first device structure 100 may additionally include a first interconnect structure 109 over the front side 102 of the first semiconductor substrate 101. The first interconnect structure 109 may include metal interconnect features 108 (e.g., metal lines and vias) formed within a dielectric material 106 (e.g., one or more inter-layer dielectric (ILD) layers and/or inter-metal dielectric (IMD) layers) that may provide connections to and/or between various first devices 107 located on and/or in the front side 102 of the first semiconductor substrate 101.

The first interconnect structure 109 may further include a first bonding layer 111 according to various embodiments of the present disclosure. The first bonding layer 111 may form the uppermost portion of the first interconnect structure 109. The first bonding layer 111 may include one or more dielectric material layers 110 composed of suitable dielectric material(s), such as silicon oxide, silicon nitride, silicon carbide, silicon carbon nitride, silicon oxynitride, a dielectric polymer material, or the like. Other suitable dielectric materials are within the contemplated scope of disclosure. The first bonding layer 111 may also include a plurality of first metal bonding pads 112 laterally surrounded by the dielectric material layer(s) 110. At least some of the first metal bonding pads 112 may be electrically coupled to underlying metal interconnect features 108 of the first interconnect structure 109. The first bonding layer 111 may have a substantially planar upper surface formed by the first metal bonding pads 112 and the surrounding dielectric material of the dielectric material layer(s) 110.

FIG. 1A illustrates a unit area (UA) of the first device structure 100. The UA of the first device structure 100 may be a portion of the first device structure 100 that may be subsequently separated (i.e., singulated) from the remainder of the first device structure 100 to provide a semiconductor die, as described further below. The UA may include a set of integrated circuit devices 107 disposed on and/or in the front side 102 of the first semiconductor substrate 101 and a first interconnect structure 109 including a first bonding layer 111 over the front side 102. In some embodiments, the set of integrated circuit devices 107 may include logic devices, and the semiconductor die formed after singulation of the first device structure 100 may be a logic die, such as a system-on-chip (SOC) die, a CPU die, a GPU die, an ASIC die, etc. The first device structure 100 may typically include a plurality of UAs that may each be separated from the first device structure 100 to form respective semiconductor dies.

FIG. 1B is a vertical cross-sectional view illustrating a portion of a second device structure 200 according to various embodiments of the present disclosure. The second device structure 200 may include a second semiconductor substrate 201 (e.g., a semiconductor wafer) that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the second semiconductor substrate 201 may be a semiconductor-on-insulator (SOI) substrate. The second semiconductor substrate 201 may include a first side 202 (i.e., front side) and a second side 203 (i.e., backside).

The second device structure 100 may include a plurality of second devices 207 disposed on and/or in the front side 202 of the second semiconductor substrate 201. The second devices 207 may include memory devices. The memory devices may include electronic circuit components, such as transistors (e.g., metal oxide semiconductor field effect transistors (MOSFETs), capacitors, and the like, that may be configured to form memory elements (i.e., memory cells) of a memory array. In some embodiments, the second devices 207 may also be configured to form peripheral circuitry, such as decoder circuitry, driver circuitry, sense amplifiers, refresh circuitry, control circuitry, and the like, for the memory array.

The second device structure 200 may additionally include a second interconnect structure 209 over the front side 202 of the second semiconductor substrate 201. The second interconnect structure 209 may be similar to the first interconnect structure 109 described above and may include at least one layer of a dielectric material 206 (e.g., an ILD layer and/or an IMD layer) having metal interconnect features 208 (e.g., metal lines and vias) embedded therein. The second interconnect structure 209 may provide connections to and/or between various second devices 207 located on and/or in the front side 202 of the second semiconductor substrate 201.

The second interconnect structure 209 may also include a second bonding layer 211 over the second interconnect structure 209. The second bonding layer 211 may be similar to the first bonding layer 111 described above and may form the uppermost portion of the second interconnect structure 209. The second interconnect structure 209 may include second metal bonding pads 212 embedded in a dielectric material 210 according to various embodiments of the present disclosure.

In some embodiments, the second interconnect structure 209 may include at least two layers of dielectric material 210 having metal features (e.g., metal lines, vias, and/or bonding pads 212) located therein. In some embodiments, each layer of the dielectric material 210 may have a thickness that is between about 0.5 μm and about 3 μm, although greater and lesser thicknesses for the layers of dielectric material 210 may also be utilized.

FIG. 1B illustrates a unit area (UA) of the second device structure 200. In some embodiments, the UA of the second device structure 200 may be a portion of the second device structure 200 that may be subsequently separated (i.e., singulated) from the remainder of the second device structure 200 to provide a memory die. The memory die may be a RAM memory die, such as a DRAM memory die or an SRAM memory die. The second device structure 200 may typically include a plurality of UAs that may each be separated from the second device structure 100 to form respective memory dies.

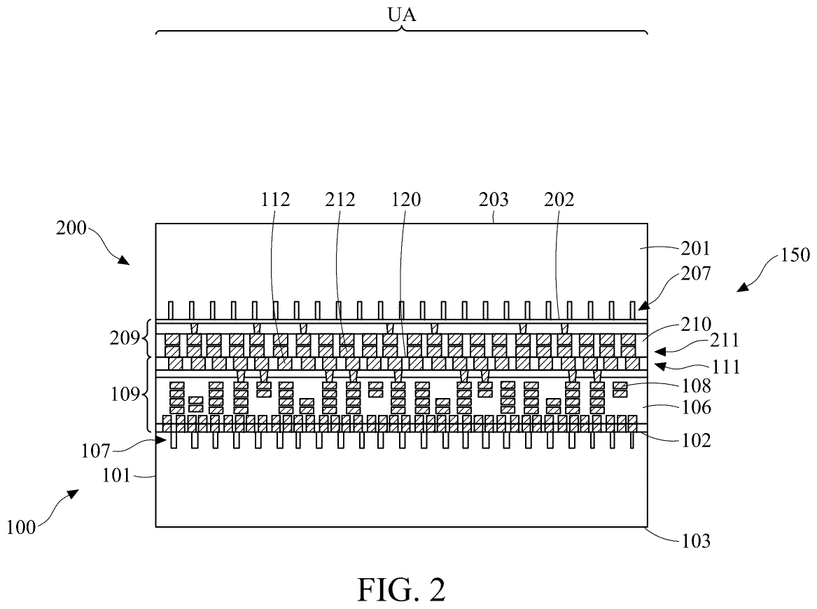

FIG. 2 is a vertical cross-sectional view illustrating the second device structure 200 bonded to the first device structure 100 to form a bonded device structure 150 according to various embodiments of the present disclosure. Referring to FIG. 2, the second device structure 200 may be aligned over the first device structure 100 such that the second bonding layer 211 on the second device structure 200 faces the first bonding layer 111 on the first device structure 100. Each UA of the second device structure 200 may be aligned over a corresponding UA of the first device structure 100. Second bonding pads 212 of the second bonding layer 111 may overlap with first bonding pads 212 of the first bonding layer 211.

Referring again to FIG. 2, in various embodiments, the second bonding layer 211 may be bonded to the first bonding layer 111 via a metal-to-metal (M-M) and dielectric-to-dielectric (D-D) direct bonding technique to couple the second device structure 200 mechanically and electrically to the first device structure 100. In some embodiments, prior to bonding the second device structure 200 to the first device structure 100, the surfaces of the first bonding layer 111 on the first device structure 100 and/or the second bonding layer 211 on the second device structure 200 may optionally be subjected to a pre-treatment process (e.g., a plasma treatment process) to promote surface activation of the first bonding layer 111 and/or the second bonding layer 211 prior to bonding the second device structure 200 to the first device structure 100. To perform the bonding process, the second device structure 200 and the first device structure 100 may be brought together such that the second bonding layer 211 of the second device structure 200 contacts the first bonding layer 111 of the first device structure 100. The second device structure 200 and the first device structure 100 may be aligned such that bonding pads 212 of the second bonding layer 211 contact corresponding bonding pads 112 of the first bonding layer 111 and dielectric material of the second bonding layer 210 contacts dielectric material 110 of the first bonding layer 111. In a direct bonding process, such as a metal-to-metal (M-M) and dielectric-to-dielectric (D-D) bonding process, bringing the first bonding layer 111 and the second bonding layer 211 into contact with one another may result in a pre-bonding process in which chemical bonds (e.g., hydrogen bridge bonds) may form at the planar interface between the dielectric material 110 of the first bonding layer 111 and the dielectric material 210 of the second bonding layer 211. In some embodiments, the pre-bonding process may be performed at ambient temperature (e.g., ~20° C.). In other embodiments, the pre-bonding process may be performed at an elevated temperature. In some embodiments, a compressive force may be applied to the second device structure 200 and the first device structure 100 during the pre-bonding process. In other embodiments, no compressive force may be applied during the pre-bonding process.

Referring again to FIG. 2, in some embodiments, an annealing process may be performed to complete the bonding of the first bonding pads 112 of the first bonding layer 111 to the second bonding pads 212 of the second bonding layer 211 according to various embodiments of the present disclosure. The annealing process may be performed at an elevated temperature, such as 100° C. or more, such as between about 150° C. and about 350° C., although lower and higher temperatures may also be utilized. In some embodiments, a compressive force may be applied to the second device structure 200 and the first device structure 100 during the annealing process. In other embodiments, no compressive force may be applied during the annealing process.

Following the bonding process, the bonded device structure 150 may include a second device structure 200 that is mechanically and electrically coupled to a first device structure 100 at a first bonding interface 120. In the embodiment of FIG. 2, bonded device structure 150 includes a configuration in which the front side 102 of the first semiconductor substrate 101 faces the front side 202 of the second semiconductor substrate 201 (i.e., a front-to-front configuration). However, it will be understood that other embodiments of the bonded device structure 150 may have a different configuration, such as a front-to-back configuration in which the front side of the first semiconductor substrate 101 faces the back side 203 of the second semiconductor substrate 201. Further, although a metal-to-metal (M-M) and dielectric-to-dielectric (D-D) direct bonding process is described herein, it will be understood that other bonding processes, such as a fusion bonding process, may be used to bond the first device structure 100 and the second device structure 200.

In some embodiments, the above-described bonding process between the first device structure 100 and the second device structure 200 may be a wafer-to-wafer bonding process in which a first device structure 100 including multiple UAs formed on a first semiconductor substrate 101 (i.e., a first semiconductor wafer) may be bonded to a second device structure 200 including corresponding UAs formed on a second semiconductor substrate 201 (i.e., a second semiconductor wafer). Alternatively, one or both of the first device structure 100 or the second device structure 200 may undergo a singulation (e.g., dicing) process to form individual dies prior to the bonding process. Individual dies may then be bonded to another wafer or another die to form the bonded device structure 150 (i.e., via a chip-to-wafer or a chip-to-chip bonding process).

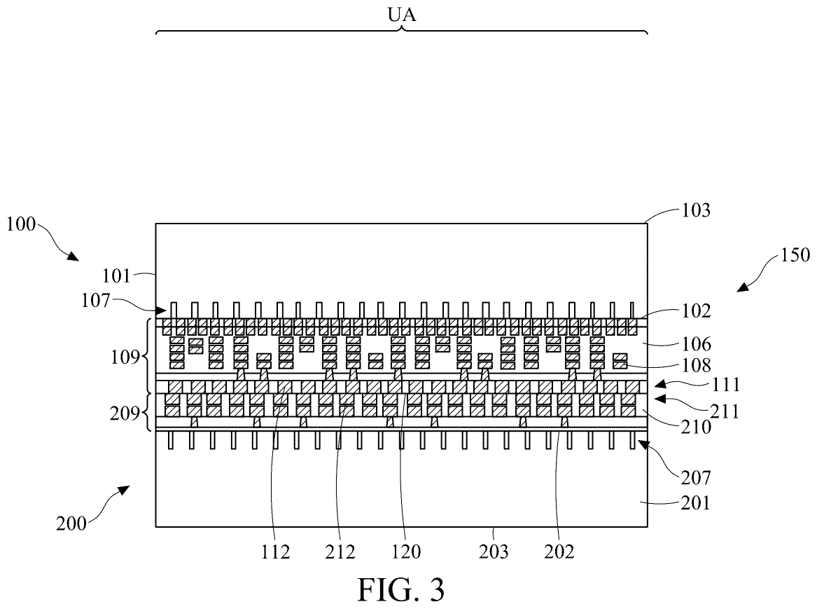

FIG. 3 is a vertical cross-sectional view illustrating the bonded device structure 150 in an inverted orientation such that the first device structure 100 is located over the second device structure 200 according to various embodiments of the present disclosure. Referring to FIG. 3, the bonded device structure 150 may be flipped over relative to the orientation shown in FIG. 2 such that the first device structure 100 may be located over and supported by the second device structure 200. The second device structure 200 including second devices 207 (e.g., memory devices) formed thereon may effectively serve as a carrier substrate for the first device structure 100.

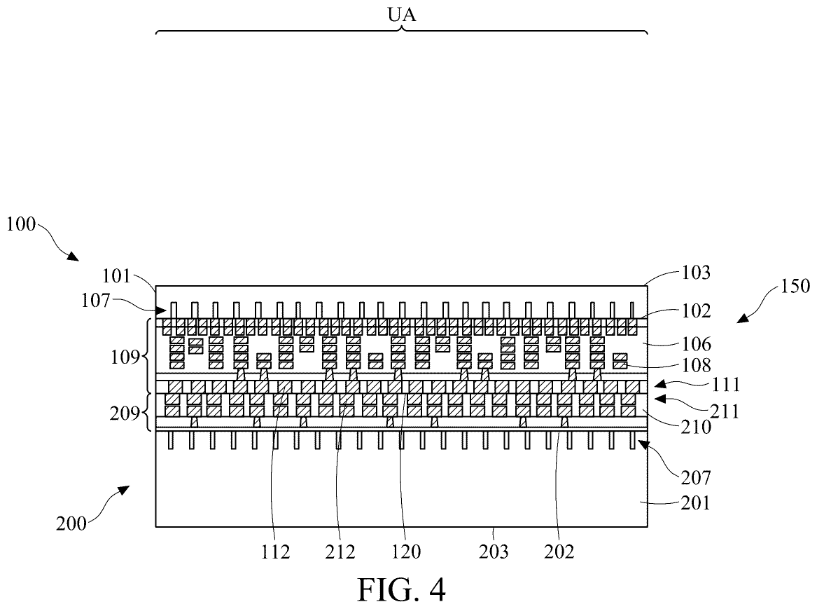

FIG. 4 is a vertical cross-sectional view of the bonded device structure 150 following a thinning process to remove a backside portion of the first semiconductor substrate 101 according to various embodiments of the present disclosure. Referring to FIG. 4, in some embodiments, a thinning process may be performed to remove a backside portion of the first semiconductor substrate 101. The thinning process may include, for example, a grinding process. In various embodiments, grinding equipment may be utilized to mechanically grind the backside 103 of the first semiconductor substrate 101 to remove material from the backside 103 of the first semiconductor substrate 101 and reduce the thickness of the first semiconductor substrate 101. Other suitable processes for thinning the first semiconductor substrate 101 are within the contemplated scope of disclosure.

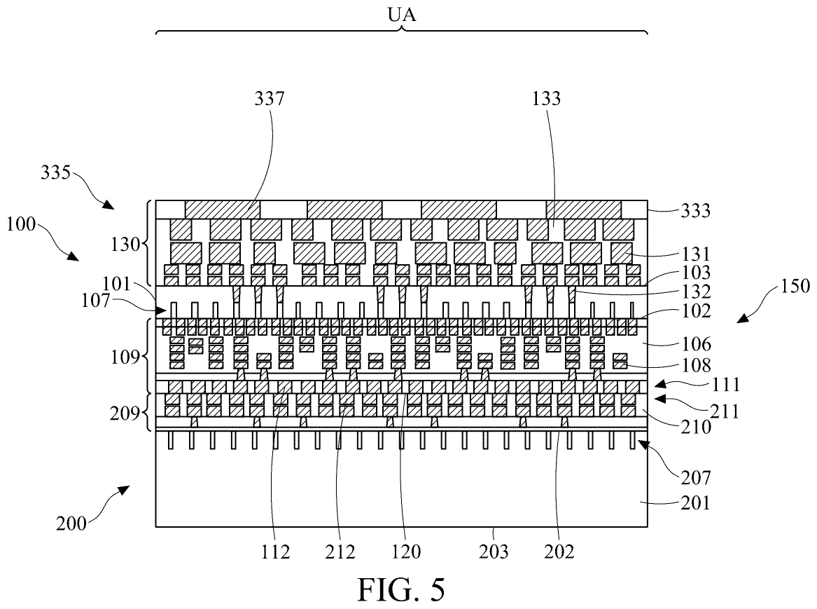

FIG. 5 is a vertical cross-sectional view of the bonded device structure 150 illustrating vias 132 formed in the first semiconductor substrate 101 and a power distribution network (PDN) structure 130 formed over the backside 103 of the first semiconductor substrate 101 according to various embodiments of the present disclosure. Referring to FIG. 5, a plurality of vias 132 may be formed in the first semiconductor substrate 101. In some embodiments, the vias 132 may be formed by forming openings in desired locations within the first semiconductor substrate 101. The openings may be formed, for example, by photolithographic techniques. A layer of photoresist may be deposited over the backside 103 of the first semiconductor substrate 101 and may be exposed to radiation (e.g., UV radiation) through a photolithographic mask (i.e., a photomask) to transfer the mask pattern to the photoresist. A developing process may be used to remove select portions of the photoresist, leaving behind a patterned mask. An etching process, such as an anisotropic etching process, may then be performed through the patterned mask to remove select portions of first semiconductor layer 101 and form openings in the first semiconductor substrate 101. Each opening may extend from the backside 103 of the first semiconductor substrate 101 through at least a portion of the thickness of the first semiconductor substrate 101. In some embodiments, the openings may extend to the integrated circuit devices 107 formed on and/or in the front side 102 of the first semiconductor substrate 101. In some embodiments, at least some of the opening may extend through the entire thickness of the first semiconductor substrate 101. Following the etching process, the patterned mask may be removed using a suitable technique, such as by ashing or dissolution using a solvent.

To form the vias 132, a dielectric material, such as silicon oxide, silicon nitride, etc., may optionally be deposited over the sidewalls of the openings. An electrically conductive material may then be deposited within the openings using a suitable deposition method. Suitable conductive materials for the vias 132 may include a metallic material, such as copper (Cu), tungsten (W), aluminum (Al), and the like, including combinations and alloys thereof. Suitable deposition processes for forming the vias 132 may include, for example, physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof. In some embodiments, excess conductive material and/or dielectric material may be removed from over the backside 103 of the first semiconductor substrate 101 using a planarization process, such as a chemical mechanical planarization process (CMP) to provide discrete vias 132 within the first semiconductor substrate 101.

The vias 132 may provide an electrical connection between the backside 103 of the first semiconductor substrate 101 and the integrated circuit devices 107 located on and/or in the front side 102 of the first semiconductor substrate 101. In some embodiments, at least some of the vias 132 may also provide an electrical connection between the backside 103 of the first semiconductor substrate 101 and the first interconnect structure 109 located over the front side 102 of the first semiconductor substrate 101. In some embodiments, at least some of the vias 132 may be configured to carry power signals to the integrated circuit devices 107 located on and/or in the front side 102 of the first semiconductor substrate 101. For example, at least some of the vias 132 may transmit power signals to active regions (e.g., source and/or drain regions) of the integrated circuit devices 107 (e.g., transistors). In some embodiments, the power signals may be transmitted through the first semiconductor substrate 101 to the active regions without being transmitted through the first interconnect structure 109. In one non-limiting embodiment, the vias 132 may transmit a positive voltage supply signal (e.g., V_{DD}) and a negative or ground voltage supply signal (e.g., V_{SS}) to the integrated circuit devices 107 located on and/or in the front side 102 of the first semiconductor substrate 101. In some embodiments, the vias 132 may include micro through-substrate vias (μTSVs) that may have a diameter of less than 10 μm.

Referring again to FIG. 5, a PDN structure 130 may be formed over the backside 103 of the first semiconductor substrate 101 and the vias 132. The PDN structure 130 may be similar to the first interconnect structure 109 as described above. The PDN structure 130 may include layer(s) of a dielectric material 133 having conductive features 131 (e.g., metal lines and vias) embedded therein. In various embodiments, the PDN structure 130 may be formed by sequentially depositing layers of dielectric material 133 using a suitable deposition process, such as a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like, including various combinations thereof. The layers of dielectric material 133 may include any suitable dielectric material(s), such as silicon oxide, silicon nitride, undoped silicate glass, doped silicate glass, silicon carbide, silicon oxynitride, silicon carbide, silicon carbon nitride, and the like, including various combinations thereof. The layers of dielectric material 133 may include IMD and/or ILD layers and may optionally also include one or more etch stop dielectric layers and/or dielectric capping layers, for example.

The conductive features 131 may be formed by forming openings in each of the layers of dielectric material 133 and depositing a conductive material within the openings, such as via a damascene or dual-damascene process. This may include, for example, performing one or more etching processes through a lithographically-patterned mask to form openings in the layers of dielectric material 133, and depositing a suitable conductive material within the openings to form the conductive features 131. The conductive features 131 may be composed of a suitable metallic material, such as copper (Cu), tungsten (W), aluminum (Al), and the like, including combinations and alloys thereof. The metallic material may be deposited using a suitable deposition method as described above.

In some embodiments, the uppermost portion of the PDN structure 130 may form a third bonding layer 335. The third bonding layer 335 may be similar to the first bonding layer 111 and the second bonding layer 211 described above, and may include bonding pads 337 surrounded by a layer of dielectric material 333.

The conductive features 131 of the PDN structure 130 may be electrically coupled to underlying vias 132 within the first semiconductor substrate 101. In the finished bonded die structure, the conductive features 131 of the PDN structure 130 may predominantly transmit power signals of the first semiconductor structure 100 (i.e., a logic die), such as the positive voltage supply signal and the negative or ground voltage supply signal. By contrast, the signals transmitted by the conductive features 108 of the first interconnect structure 109 may be predominantly include the internal or “I/O” signals of the first semiconductor structure 100, such as control signals, data signals, address signals, clock signals, and the like. Typically, dimensions (such as width or etc.) of the conductive features (i.e., lines and vias) that carry power signals for a semiconductor die are larger than the corresponding dimensions (such as width or etc.) of the conductive features that carry the I/O signals of the semiconductor die. Thus, in various embodiments, the average width of the conductive features 131 of the PDN structure 130 may be greater than the average width of the conductive features 108 of the first interconnect structure 109.

As discussed above, separating the power signals and the I/O signals on opposite sides of the first semiconductor substrate 101 may provide a number of advantages, including reduced noise and improved power and signal integrity. In addition, the PDN structure 130 located over the backside 103 of the first semiconductor substrate 101 may provide an additional thermal dissipation path, which may provide improved thermal management and enhanced die performance.

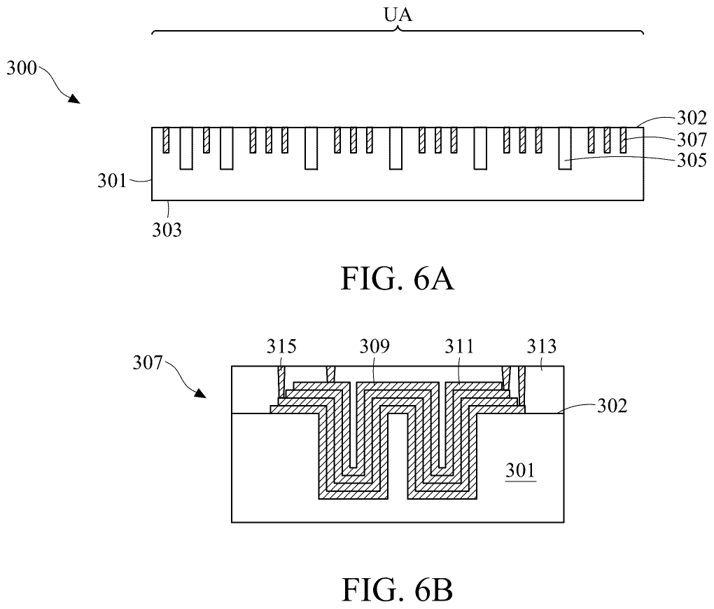

FIG. 6A is a vertical cross-sectional view illustrating a portion of a third device structure 300 according to various embodiments of the present disclosure. The third device structure 300 may include a third semiconductor substrate 301 (e.g., a semiconductor wafer) as described above with reference to FIGS. 1A and 1B. The third semiconductor substrate 301 may include a first side 302 (i.e., front side) and a second side 303 (i.e., backside). The third device structure 300 may include a plurality of vias 305 extending from the front side 302 of the third semiconductor substrate 301 through at least a portion of the thickness of the third semiconductor substrate 301. In the embodiment shown in FIG. 6A, the vias 305 may be formed such that they extend partway through the thickness of the third semiconductor substrate 301. In other embodiments, the vias 305 may be formed to extend through the entire thickness of the third semiconductor substrate 301.

The vias 305 of the third device structure 300 may be similar to the vias 132 described above with reference to FIG. 5. A plurality of openings may be formed in the front side 302 the third semiconductor substrate 301 using photolithographic and etching steps as described above. A dielectric material may optionally be deposited over the sidewalls of the openings, and an electrically conductive material may be deposited within the openings using a suitable deposition method. A planarization process, such as CMP may be used to remove excess conductive material and/or dielectric material from over the front side 302 of the third semiconductor substrate 301 to provide discrete vias 305 within the third semiconductor substrate 301.

FIG. 6B is an enlarged vertical cross sectional view of a portion of the third device structure 300 that illustrates a DTC structure 307 according to various embodiments of the present disclosure. The DTC structure 307 may include alternating layers of dielectric and conductive materials that may extend vertically into the third semiconductor substrate 301. In some embodiments, the DTC structure 307 may extend to a depth of several microns, such between about 5-10μm or more, into the third semiconductor substrate 301. The DTC structure 307 may be formed by performing an etching process through a lithographic mask to form one or more trenches in the front side 302 of the third semiconductor substrate 301. In the exemplary embodiment shown in FIG. 6B, a pair of adjacent trenches may be formed in the third semiconductor substrate 301, although it will be understood that more or fewer trenches may be formed. Layers of dielectric and conductive materials may then be alternately deposited over the front side 302 of the third semiconductor substrate 301 and over the side surfaces and bottom surfaces of the trenches using suitable deposition processes as described above. Suitable materials for the dielectric layers 309 may include, for example, silicon oxide, silicon nitride, silicon carbide, silicon carbon nitride, silicon oxynitride, a high-k dielectric material such as hafnium oxide, zinc oxide, tantalum pentoxide, aluminum oxide, titanium oxide, hafnium silicate and/or zinc silicate, including various combinations thereof. Suitable materials for the conductive layers 311 may include, for example, a metallic material, such as copper, aluminum, tin, gold silver, tungsten, titanium, including combinations and alloys thereof, and/or a conductive semiconductor material such as doped polysilicon. In some embodiments, a diffusion barrier layer (not shown in FIG. 6B) may optionally be disposed between one or more of the conductive layers 311 and the adjacent dielectric layer(s) 309 and/or the third semiconductor substrate 301. The diffusion barrier layer may include, for example, Ta, TaN, Ti, TiN, CoW, or combinations thereof. Other suitable materials for the dielectric layers 309, the conductive layers 311 and the optional diffusion barrier layer(s) are within the contemplated scope of disclosure.

The dielectric layers 309 and the conductive layers 311 deposited over the front side 302 of the third semiconductor substrate 301 and within the trench(es) may be patterned by performing an etching process through a photolithographically-defined mask to provide a DTC structure 307 such as shown in FIG. 6B. Each of the dielectric layers 309 and the conductive layers 311 may form a “U”-shape in a vertical cross section view such that the layers 309 and 311 include vertically extending portions over the side surfaces of the trenches and a horizontally extending portion over the bottom surfaces of the trenches. As discussed above, the trenches may be several microns, such as about 5-10 μm or more in depth, such that the dielectric layers 309 and the conductive layers 311 may extend parallel to one another over a relatively large vertical distance. This may enable increased capacitance in a compact area of the third device structure 300. Portions of the dielectric layers 309 and the conductive layers 311 located outside of the trenches may extend in a horizontal direction over the front side 302 of the third semiconductor substrate 301. In the embodiment shown in FIG. 6B, the dielectric layers 309 and the conductive layers 311 extend continuously between the pair of adjacent trenches over the front side 302 of the third semiconductor substrate 301. However, it will be understood that other configurations for the DTC structure 307 are within the contemplated scope of disclosure.

In some embodiments, one or more dielectric material layers 313 may be formed over the DTC structure 307 and the front side 302 of the third semiconductor substrate 301. Contact vias 315 may be formed through the dielectric material layer(s) 313 to contact the conductive layers 311 of the DTC structure 307.

Referring again to FIG. 6A, a plurality of DTC structures 307 may be formed in the third semiconductor substrate 301 located around and between the vias 315. In various embodiments, the DTC structures 307 may help to stabilize the power signals provided to the bonded die structure over the vias 315 and reduce noise.

FIG. 6A illustrates a unit area (UA) of the third device structure 300. In some embodiments, the UA of the third device structure 300 may be a portion of the third device structure 300 that may be subsequently separated (i.e., singulated) from the remainder of the third device structure 300 to provide a DTC die. The third device structure 300 may typically include a plurality of UAs that may each be separated from the third device structure 300 to form respective DTC dies.

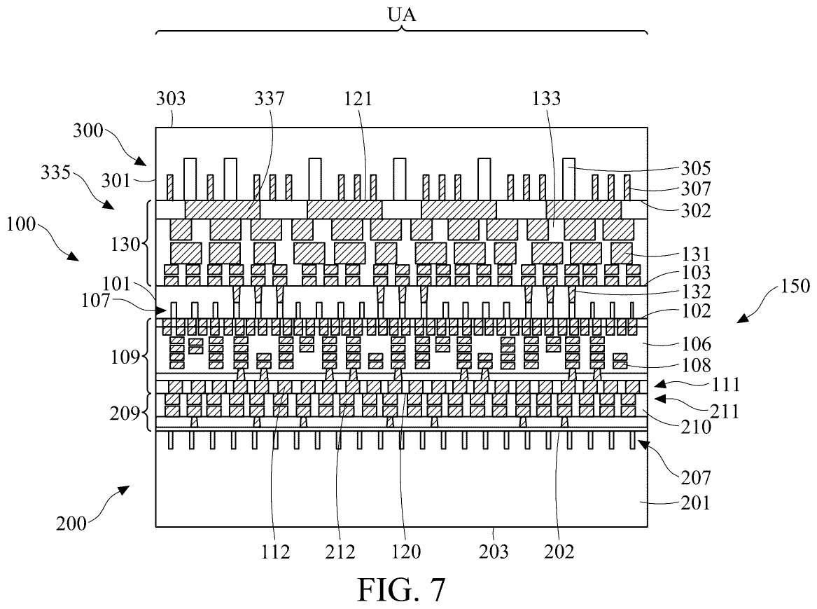

FIG. 7 is a vertical cross-sectional view of the bonded device structure 150 including the third device structure 300 bonded over the PDN structure 130 according to various embodiments of the present disclosure. Referring to FIG. 7, a bonding process may be used to bond the third device structure 150 to the bonded device structure 150. In some embodiments, the bonding process may be a direct bonding process, such as a metal-to-metal (M-M) and dielectric-to-dielectric (D-D) bonding process as described above. In some embodiments, a bonding layer (not expressly shown in FIG. 7) including metal bonding pads surrounded by a dielectric material as described above may be formed over the front side 302 of the third semiconductor substrate 301 of the third device structure 300. The bonding layer on the third device structure 300 may be aligned over the corresponding bonding layer 335 in the upper portion of the PDN structure 130 such that bonding pads on the third device structure 300 overlap with corresponding bonding pads 337 of the PDN structure 130. An M-M and D-D direct bonding process as previously described may then be performed to bond the third device structure 300 to the PDN structure 130 at a second bonding interface 121. In other embodiments, the bonding layer on the third device structure 300 may be omitted, and the third semiconductor structure 300 may be directly bonded to the PDN structure 130 via a fusion bonding method or other technique. The second bonding interface 121 of the bonded device structure 150 may be located between the PDN structure 130 and the third semiconductor substrate 301.

Following the bonding process, the bonded device structure 150 may include a third device structure 200 that is mechanically and electrically coupled to the PDN structure 130 at a second bonding interface 121. The vias 305 and DTC structures 307 extending within the third semiconductor substrate 301 may be electrically coupled to conductive features 131 of the PDN structure 130 across the second bonding interface 121. In the embodiment of FIG. 2, bonded device structure 150 includes a configuration in which the front side 302 of the third semiconductor substrate 301 faces the backside 103 of the first semiconductor substrate 101 (i.e., a front-to-back configuration). However, it will be understood that other embodiments of the bonded device structure 150 may have a different configuration, such as a back-to-back configuration in which the back side 303 of the third semiconductor substrate 301 faces the back side 103 of the first semiconductor substrate 301.

In some embodiments, the above-described bonding process between the third device structure 300 and the PDN structure 130 over the backside 103 of the first device structure 100 may be a wafer-to-wafer bonding process in which a third device structure 300 including multiple UAs formed on a third semiconductor substrate 301 (i.e., a third semiconductor wafer) may be bonded to first device structure 100 including corresponding UAs formed on a first semiconductor substrate 101 (i.e., a first semiconductor wafer). Alternatively, one or both of the third device structure 300 or the first device structure 100 may undergo a singulation (e.g., dicing) process to form individual dies prior to the bonding process. Individual dies may then be bonded to another wafer or another die to form a bonded device structure 150 (i.e., via a chip-to-wafer or a chip-to-chip bonding process) as shown in FIG. 7.

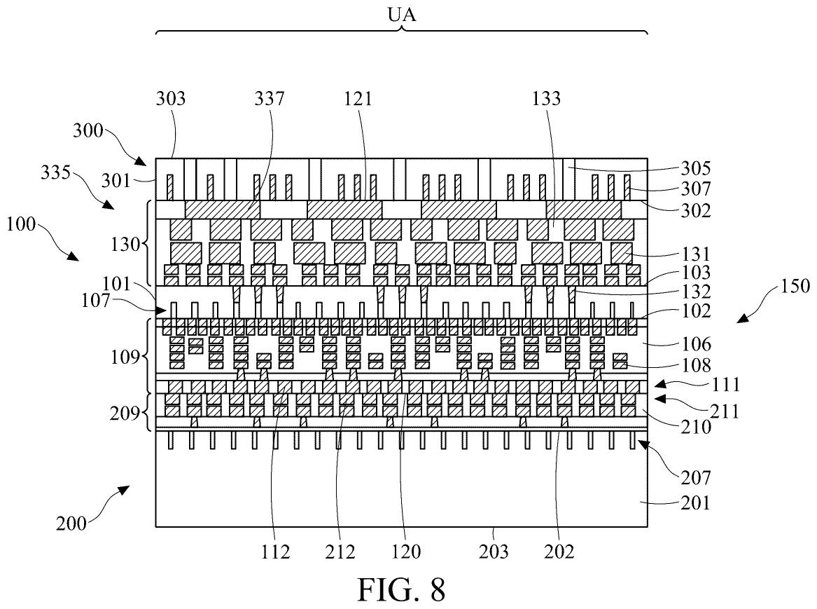

FIG. 8 is a vertical cross-section view of the bonded device structure 150 following a thinning process to remove a backside portion of the third semiconductor substrate 301 according to various embodiments of the present disclosure. Referring to FIG. 8, in some embodiments, a thinning process may optionally be performed to remove a backside portion of the third semiconductor substrate 301. The thinning process may include, for example, a grinding process, such as described above with reference to FIG. 4. Other suitable processes for thinning the third semiconductor substrate 301 are within the contemplated scope of disclosure. The thinning process may reveal the vias 305 on the backside 303 of the third semiconductor substrate 301. In some embodiments, the thinning process may be utilized to provide a desired thickness for the third device structure 300 (e.g., a DCT die) in the final bonded die structure. In various embodiments, following the thinning process the third device structure 300 may have a thickness that is between about 10 μm and about 200 μm, although greater and lesser thicknesses for the third device structure 300 are within the contemplated scope of disclosure.

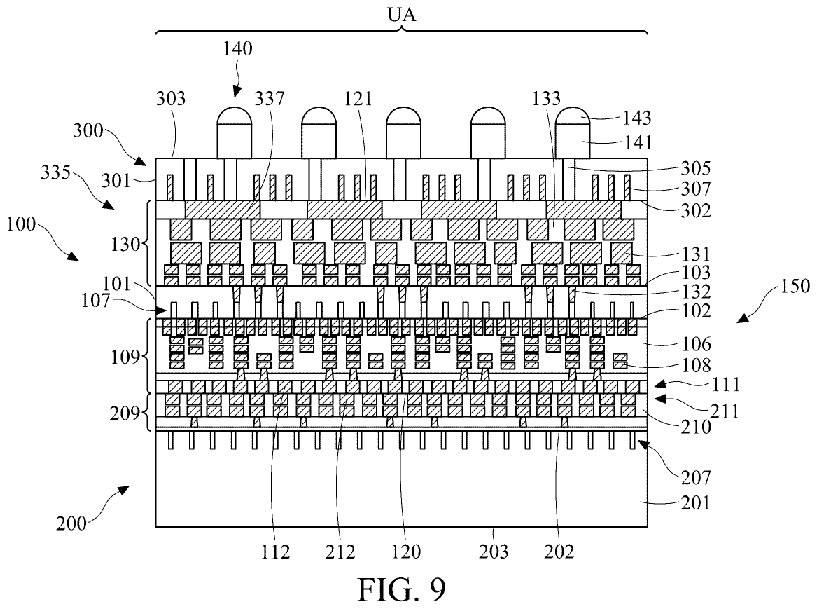

FIG. 9 is a vertical cross-section view of the bonded device structure 150 including bonding structures 140 located over the backside 303 of the third semiconductor substrate 301 according to various embodiments of the present disclosure. Referring to FIG. 9, a plurality of bonding structures 140 may be formed over the backside 303 of the third semiconductor substrate 301 of the third semiconductor structure 300. The bonding structures 140 may include, for example, microbump bonding structures. In some embodiments, the bonding structures 140 may include metallic pillars 141 including suitable metal material(s), such as copper, formed over the backside 303 of the third semiconductor substrate 301. The metallic pillars 141 may be formed via a suitable deposition process as described above, such as by a PVD or electrochemical deposition process. A solder material portion 143 may be provided over the upper surfaces of each of the metallic pillars 141. It will be understood that other suitable bonding structures 140, such as bonding pads including controlled collapse (C4) solder material portions (e.g., solder balls), may also be utilized. The bonding structures 140 may be electrically connected to vias 305 extending through the third semiconductor substrate 301 of the third semiconductor structure 300. In embodiments that do not include a third semiconductor structure 300, the bonding structures 140 may be formed over the PDN structure 130 located on the backside 103 of the first semiconductor substrate 101 of the first semiconductor device structure 100, and may be electrically connected to conductive features 131 of the PDN structure 130.

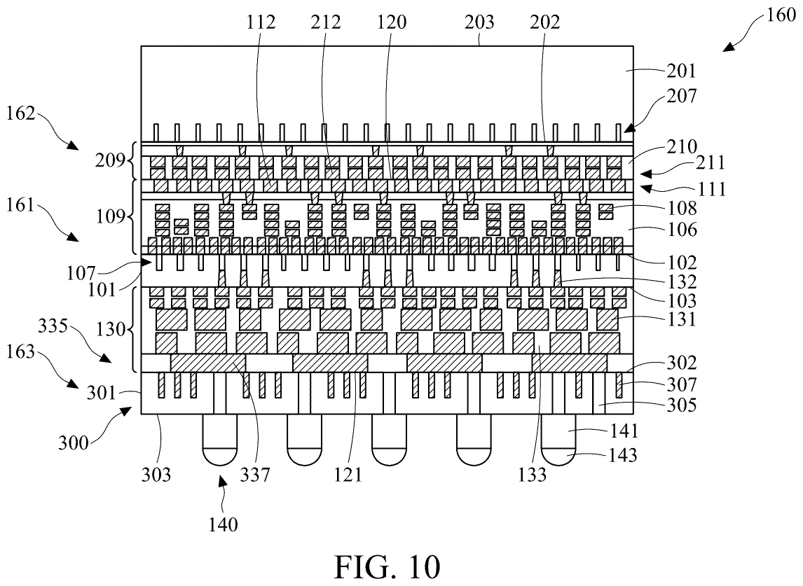

FIG. 10 is a vertical cross-sectional view of a bonded die structure 160 according to various embodiments of the present disclosure. Referring to FIG. 10, in some embodiments, a dicing process may be performed through one or more of the first device structure 100, the second device structure 200, and the third device structure 300 to provide a bonded die structure 160 including a first semiconductor die 161, a memory die 162, and a DTC die 163. In some embodiments, the first semiconductor die 161 may include a single UA of the first device structure 100, the memory die 162 may include a single UA of the second device structure 200, and the DTC die 163 may include a single UA of the third device structure 300. In some embodiments, following the dicing process, the first semiconductor die 161, the memory die 162 and the DTC die 163 may have continuous side surfaces. In some embodiments, the continuous side surfaces of the bonded die structure 160 may include side surfaces of the first semiconductor substrate 101, the second semiconductor substrate 201 and the third semiconductor substrate 301.

Referring again to FIG. 10, the orientation of the bonded die structure 160 may be inverted (i.e., flipped over) relative to the orientation of FIG. 9 such that the bonding structures 140 may be located on a lower surface of the bonded die structure 160. The bonding structures 140 may enable the bonded die structure to be mounted to a support structure, such as a substrate or an interposer of a semiconductor package.

In some embodiments, the backside 203 of the second semiconductor substrate 201 may be thinned using a suitable thinning technique as described above. The thinning of the second semiconductor substrate 201 may account for height differences in the bonded die structure 160 compared to related die structures in which the first device structure 100 may be mounted to a (non-functional) carrier substrate. For example, the thinning process may account for height variations due to the presence of the second interconnect structure 209 of the memory die 162, the DTC die 163 and/or the PDN structure 130.

The bonded die structure 160 according to various embodiments may include a first semiconductor die 161, which may be a logic die (e.g., an SoC die, a CPU die, a GPU die, an ASIC die, etc.) having a first semiconductor substrate 101, integrated circuit devices 107 located on and/or in the front side 102 of the first semiconductor substrate 101, a first interconnect structure 109 over the front side 102 of the first semiconductor substrate 101 and a PDN structure 130 over a back side 103 of the first semiconductor substrate 101. The bonded die structure 160 may further include at least one additional functional die bonded to the first semiconductor die 161. In some embodiments, the at least one functional die may include a memory die 162. The memory die 162 may include a second semiconductor substrate 201 having memory devices 207 located on and/or in a front side 202 of the second semiconductor substrate 201 and a second interconnect structure 209 over the front side 202 of the second semiconductor substrate 201. The first semiconductor die 161 may be mechanically and electrically coupled to the memory die 162 at a first bonding interface 120 located between the first interconnect structure 109 and the second interconnect structure 209.

In various embodiments, the memory die 162 may be a RAM die, such as a DRAM and/or SRAM die. In some embodiments, the memory die 162 may be part of a stack of memory dies. That is, one or more additional memory dies may be located over the backside 203 of the second semiconductor substrate 201 and may be electrically connected to the memory die 162 by TSVs extending through the second semiconductor substrate 201.

Alternatively, or in addition, the additional functional die may include a DTC die 163. The DTC die 163 may include a plurality of vias 305 and DTC structures 307 located in a third semiconductor substrate 301. The first semiconductor die 161 may be mechanically and electrically coupled to the DTC die 163 at a second bonding interface 121 located between the PDN structure 130 and the third semiconductor substrate 301.

In various embodiments, the bonded die structure 160 may provide increased functionality by providing a memory die bonded to the first semiconductor die 161 rather than a non-functional carrier substrate as in related devices. Further, by providing a PDN structure 130 and optionally a DTC die 163 on the backside 103 of the first semiconductor substrate 101, opposite the memory die 162, signal and power integrity of the bonded die structure 160 may be improved.

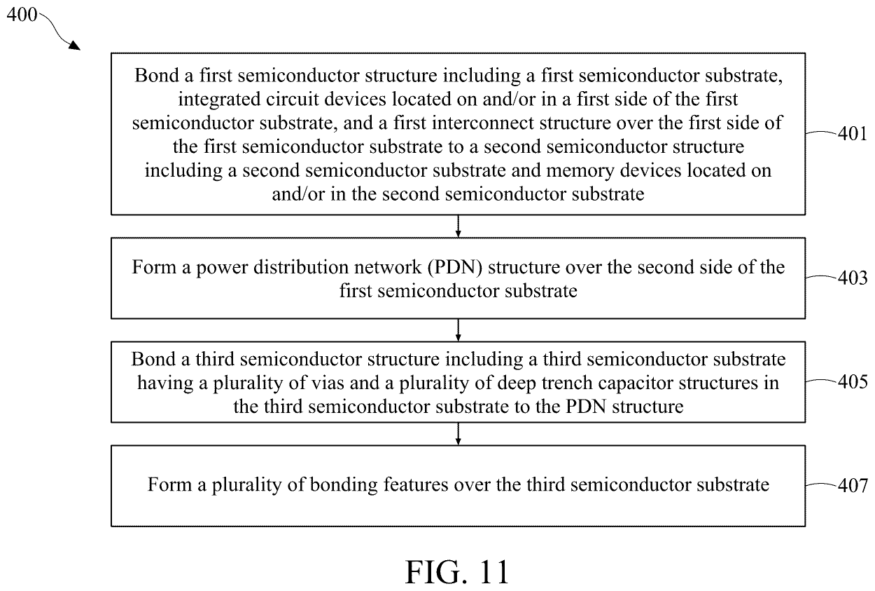

FIG. 11 is a flowchart illustrating a method 400 of fabricating a bonded die structure 160 according to various embodiments of the present disclosure. Referring to FIGS. 1A-2 and 11, in step 401 of method 400, a first semiconductor structure 100 including a first semiconductor substrate 101, integrated circuit devices 107 located on and/or in a first side 102 of the first semiconductor substrate 101, and a first interconnect structure 109 over the first side 102 of the first semiconductor substrate 101 may be bonded to a second semiconductor structure 200 including a second semiconductor substrate 201 and memory devices 207 located on and/or in the second semiconductor substrate 201. Referring to FIGS. 3-5 and 11, in step 403 of method 400, a PDN structure 130 may be formed over the second side 203 of the first semiconductor substrate 101. Referring to FIGS. 6A-7 and 11, in step 405 of method 400, a third semiconductor structure 300 including a third semiconductor substrate 301 having a plurality of vias 305 and a plurality of deep trench capacitor structures 307 in the third semiconductor substrate 301 may be bonded to the PDN structure 130. Referring to FIGS. 8 and 11, in step 407 of method 400, bonding features 140 may be formed over the third semiconductor substrate 301.

Referring to all drawings and according to various embodiments of the present disclosure, a bonded die structure 160 includes a logic die 161 including a first semiconductor substrate 101 having a first side 102 and a second side 103, integrated circuit devices 107 located on and/or in the first side 102 of the first semiconductor substrate 101, a first interconnect structure 109 over the first side 102 of the first semiconductor substrate 101, and a power distribution network structure 130 over the second side 103 of the first semiconductor substrate 101, and a memory die 162 including a second semiconductor substrate 201 having a first side 202 and a second side 203, memory devices 207 located on and/or in the first side 202 of the second semiconductor substrate 201, and a second interconnect structure 209 over the first side 202 of the second semiconductor substrate 201, where the logic die 161 is mechanically and electrically coupled to the memory die 162 at a first bonding interface 120 located between the first interconnect structure 109 and the second interconnect structure 209, and a plurality of bonding features 140, the power distribution network structure 130 located between the second side 103 of the first semiconductor substrate 101 and the plurality of bonding features 140.

In one embodiment, the logic die 161 includes at least one of a system-on-chip (SOC) die, a CPU die, a GPU die, and an ASIC die, and the memory die 162 includes a RAM die.

In another embodiment, the first interconnect structure 109 includes a dielectric material 110 having conductive features 108 therein, the PDN structure 130 includes a dielectric material 133 having conductive features 131 therein, the conductive features 131 of the PDN structure 130 predominantly transmit power signals for the logic die 161, and the conductive features 108 of the first interconnect structure 109 predominantly transmit internal signals of the logic die 161.

In another embodiment, the first semiconductor substrate 101 includes a plurality of vias 132 extending at least partially through the first semiconductor substrate 101 and electrically coupling conductive features 131 of the PDN structure 130 to the integrated circuit devices 107 located on and/or in the first side 102 of the first semiconductor substrate 101.

In another embodiment, the vias 131 transmit power signals through the first semiconductor substrate 101 to active regions of the integrated circuit devices 107 without the power signals being transmitted through the first interconnect structure 109.

In another embodiment, an average width of the conductive features 131 of the PDN structure 130 is greater than an average width of the conductive features 108 of the first interconnect structure 109.

In another embodiment, the bonded die structure 160 further includes a deep trench capacitor (DTC) die 163 including a third semiconductor substrate 301, a plurality of vias 305 extending through the third semiconductor substrate 301, and a plurality of deep trench capacitor structures 307 extending into the third semiconductor substrate 301, where the DTC die 163 is mechanically and electrically coupled to the logic die 161 at a second bonding interface 121 located between the PDN structure 130 and the third semiconductor substrate 301.

In another embodiment, the third semiconductor substrate 301 includes a first side 302 and a second side 303, the deep trench capacitor structures 307 extend from the first side 302 of the third semiconductor substrate 301 to a depth of at least 5 μm into the third semiconductor substrate 301, the bonding features 140 are located over the second side 303 of the third semiconductor substrate 301, and the plurality of vias 305 extending through the third semiconductor substrate 301 electrically connect the bonding features 140 to conductive features 131 of the PDN structure 130.

In another embodiment, the logic die 161, the memory die 162, and the DTC die 163 have continuous side surfaces.

Another embodiment is drawn to a bonded device structure 160 including a first semiconductor die 161 including a first semiconductor substrate 101 having a first side 102 and a second side 103, integrated circuit devices 107 located on and/or in the first side 102 of the first semiconductor substrate 101, a first interconnect structure 109 over the first side 102 of the first semiconductor substrate 101, and a power distribution network (PDN) structure 130 over the second side 103 of the first semiconductor substrate 101, and a deep trench capacitor (DTC) die 163 including a second semiconductor substrate 301 having a first side 302 and a second side 303, a plurality of vias 305 extending through the second semiconductor substrate 301, and a plurality of deep trench capacitor structures 307 extending into the second semiconductor substrate 301, where the DTC die 301 is mechanically and electrically coupled to the first semiconductor die 161 at a first bonding interface 121 located between the PDN structure 130 and the first side 302 of the second semiconductor substrate 301, and a plurality of bonding features 140 located over the second side 303 of the second semiconductor substrate 301.

In one embodiment, a thickness of the DTC die 163 is ≥10 μm and ≤200 μm.

In another embodiment, the deep trench capacitor structures extend into the second semiconductor substrate 301 to a depth of at least 5 μm from the first side 302 of the second semiconductor substrate 301.

In another embodiment, the deep trench capacitor structures 307 include trenches formed in the front side 302 of the second semiconductor substrate 301 and alternating layers of conductive and dielectric materials 311, 309 over the side surfaces and bottom surfaces of the trenches.

In another embodiment, the alternating layers of conductive and dielectric materials 311, 309 extend continuously between adjacent trenches over the front side 302 of the second semiconductor substrate 301.

In another embodiment, the bonded die structure 160 further includes a third semiconductor substrate 201 over the first interconnect structure 109.

In another embodiment, the third semiconductor substrate 201 includes a plurality of memory elements 207 located on and/or in the third semiconductor substrate 201.

Another embodiment is drawn to a method of fabricating a bonded die structure 160 that includes bonding a first semiconductor structure 100 including a first semiconductor substrate 101, integrated circuit devices 107 located on and/or in a first side 102 of the first semiconductor substrate 101, and a first interconnect structure 109 over the first side 102 of the first semiconductor substrate 101 to a second semiconductor structure 200 including a second semiconductor substrate 201 and memory devices 207 located on and/or in the second semiconductor substrate 201, forming a power distribution network (PDN) structure 130 over the second side 103 of the first semiconductor substrate 101, bonding a third semiconductor structure 300 including a third semiconductor substrate 301 having a plurality of vias 305 and a plurality of deep trench capacitor (DTC) structures 307 in the third semiconductor substrate 301 to the PDN structure 130, and forming a plurality of bonding features 140 over the third semiconductor substrate 301.

In one embodiment, the method further includes performing a thinning process on the second side 103 of the first semiconductor substrate 101 while the first semiconductor structure 100 is supported on the second semiconductor structure 200, and forming a plurality of vias 132 in the second side 103 of the first semiconductor substrate 101 and electrically connected to the integrated circuit devices 107 of the first semiconductor structure 100, where the PDN structure 130 is formed over the second side 103 of the first semiconductor substrate 101 and the plurality of vias 132 such that conductive features 131 of the PDN structure 130 are electrically connected to the plurality of vias 132.

In another embodiment, the plurality of vias 305 and the plurality of deep trench capacitor (DTC) structures 307 of the third semiconductor structure 300 extend from a first side 302 of the third semiconductor substrate 301 that faces the PDN structure 130, and the method further includes performing a thinning process on a second side 303 of the third semiconductor substrate 301 to expose the plurality of vias 305 on the second side 303 of the third semiconductor substrate 301, where the plurality of bonding features 140 formed are formed over a second side 303 of the third semiconductor substrate 301 and are electrically connected to the plurality of vias 305 extending through the third semiconductor substrate 301.

In another embodiment, the first semiconductor structure 100 is bonded to the second semiconductor structure 200 using a direct bonding process, and the third semiconductor structure 300 is bonded to the PDN structure 130 using a direct bonding process.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A semiconductor structure, comprising:
a logic die, comprising:
a first semiconductor substrate having a first side and a second side;
integrated circuit devices located on and/or in the first side of the first semiconductor substrate;
a first interconnect structure over the first side of the first semiconductor substrate; and
a power distribution network (PDN) structure over the second side of the first semiconductor substrate;
a memory die, comprising:
a second semiconductor substrate having a first side and a second side;
memory devices located on and/or in the first side of the second semiconductor substrate; and
a second interconnect structure over the first side of the second semiconductor substrate, wherein the logic die is mechanically and electrically coupled to the memory die at a first bonding interface located between the first interconnect structure and the second interconnect structure; and
a plurality of bonding features, wherein the PDN structure locates between the second side of the first semiconductor substrate and the plurality of bonding features.

2. The semiconductor structure of claim 1, wherein:
the logic die comprises at least one of a system-on-chip (SOC) die, a CPU die, a GPU die, and an ASIC die, and
the memory die comprises a RAM die.

3. The semiconductor structure of claim 1, wherein:
the first interconnect structure comprises a dielectric material having conductive features therein,
the PDN structure comprises a dielectric material having conductive features therein,
the conductive features of the PDN structure predominantly transmit power signals for the logic die, and
the conductive features of the first interconnect structure predominantly transmit internal signals of the logic die.

4. The semiconductor structure of claim 3, wherein the first semiconductor substrate comprises a plurality of vias extending at least partially through the first semiconductor substrate and electrically coupling the conductive features of the PDN structure to the integrated circuit devices located on and/or in the first side of the first semiconductor substrate.

5. The semiconductor structure of claim 4, wherein the vias are configured to transmit power signals through the first semiconductor substrate to active regions of the integrated circuit devices without the power signals being transmitted through the first interconnect structure.

6. The semiconductor structure of claim 3, wherein an average width of the conductive features of the PDN structure is greater than an average width of the conductive features of the first interconnect structure.

7. The semiconductor structure of claim 1, further comprising:
a deep trench capacitor (DTC) die, comprising:
a third semiconductor substrate;
a plurality of vias extending through the third semiconductor substrate; and
a plurality of deep trench capacitor structures extending into the third semiconductor substrate, wherein:
the DTC die is mechanically and electrically coupled to the logic die at a second bonding interface located between the PDN structure and the third semiconductor substrate.

8. The semiconductor structure of claim 7, wherein the third semiconductor substrate comprises a first side and a second side, the deep trench capacitor structures extend from the first side of the third semiconductor substrate to a depth of at least 5 μm into the third semiconductor substrate, the bonding features are located over the second side of the third semiconductor substrate, and the plurality of vias extending through the third semiconductor substrate electrically connect the bonding features to conductive features of the PDN structure.

9. The semiconductor structure of claim 7, wherein the logic die, the memory die, and the DTC die have continuous side surfaces.

10. A semiconductor structure, comprising:
a first semiconductor die, comprising:
a first semiconductor substrate having a first side and a second side;
integrated circuit devices located on and/or in the first side of the first semiconductor substrate;
a first interconnect structure over the first side of the first semiconductor substrate; and
a power distribution network (PDN) structure over the second side of the first semiconductor substrate;
a deep trench capacitor (DTC) die, comprising:
a second semiconductor substrate comprising a first side and a second side;
a plurality of vias extending through at least a portion of the second semiconductor substrate; and
a plurality of deep trench capacitor structures extending into the at least the portion of the second semiconductor substrate, wherein:
the DTC die is mechanically and electrically coupled to the first semiconductor die at a first bonding interface located between the PDN structure and the first side of the at least the portion of the second semiconductor substrate; and
a plurality of bonding features located over the second side of the at least the portion of the second semiconductor substrate.

11. The semiconductor structure of claim 10, wherein a thickness of the DTC die is ≥10 μm and ≤200 μm.

12. The semiconductor structure of claim 10, wherein the deep trench capacitor structures extend into the at least the portion of the second semiconductor substrate to a depth of at least 5 μm from the first side of the second semiconductor substrate.

13. The semiconductor structure of claim 12, wherein the deep trench capacitor structures comprise trenches formed in the front side of the at least the portion of the second semiconductor substrate and alternating layers of conductive and dielectric materials over respective side surfaces and bottom surfaces of the trenches.

14. The semiconductor structure of claim 13, wherein the alternating layers of conductive and dielectric materials extend continuously between adjacent trenches over the front side of the at least the portion of the second semiconductor substrate.

15. The semiconductor structure of claim 10, further comprising:
a third semiconductor substrate over the first interconnect structure.

16. The semiconductor structure of claim 15, wherein the third semiconductor substrate comprises a plurality of memory elements located on and/or in the third semiconductor substrate.

17. A method of fabricating a semiconductor structure, comprising:
bonding a first semiconductor structure comprising a first semiconductor substrate, integrated circuit devices located on and/or in a first side of the first semiconductor substrate, and a first interconnect structure over the first side of the first semiconductor substrate to a second semiconductor structure comprising a second semiconductor substrate and memory devices located on and/or in the second semiconductor substrate;
forming a power distribution network (PDN) structure over the second side of the first semiconductor substrate;
bonding a third semiconductor structure comprising a third semiconductor substrate having a plurality of vias and a plurality of deep trench capacitor (DTC) structures in the third semiconductor substrate to the PDN structure; and
forming a plurality of bonding features over the third semiconductor substrate.

18. The method of claim 17, further comprising:
performing a thinning process on the second side of the first semiconductor substrate while the first semiconductor structure is supported on the second semiconductor structure; and
forming a plurality of vias in the second side of the first semiconductor substrate and electrically connected to the integrated circuit devices of the first semiconductor structure, wherein the PDN structure is formed over the second side of the first semiconductor substrate and the plurality of vias such that conductive features of the PDN structure are electrically connected to the plurality of vias.

19. The method of claim 18, wherein the plurality of vias and the plurality of deep trench capacitor (DTC) structures of the third semiconductor structure extend from a first side of the third semiconductor substrate that faces the PDN structure, and the method further comprises:
performing a thinning process on a second side of the third semiconductor substrate to expose the plurality of vias on the second side of the third semiconductor substrate, wherein the plurality of bonding features formed over a second side of the third semiconductor substrate and are electrically connected to the plurality of vias extending through the third semiconductor substrate.

20. The method of claim 17, wherein the first semiconductor structure is bonded to the second semiconductor structure using a direct bonding process, and the third semiconductor structure is bonded to the PDN structure using a direct bonding process.
